(19) United States
(12) Patent Application Publication
(10) Pub. No.: US 2008/0042281 A1
(43) Pub. Date: Feb. 21, 2008

(54) Semiconductor device and semiconductor device fabrication method

(75) Inventor: Kazuhide Abe, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/826,472

(22) Filed: Jul. 16, 2007

(30) Foreign Application Priority Data
Aug. 15, 2006 (JP) 2006-221379

(51) Int. Cl. H01L 23/532; H01L 21/4763

(52) U.S. Cl. 257/751; 438/653; 257/E21.495; 257/E23.155

(57) ABSTRACT

A semiconductor device includes: a semiconductor substrate; a first insulation film that is formed on the semiconductor substrate and includes grooves (including through holes); a metal film that is formed inside the grooves and includes a first metal (e.g., titanium (Ti)); a glue film formed on a side surface of the metal film; and a metal plating film that is formed on a side surface of the glue film, comprises a second metal (e.g., copper (Cu)), and includes a region having the first metal (e.g., Ti) in a surface that contacts the glue film. Thus, there are provided a semiconductor device and a semiconductor device fabrication method that have excellent adhesiveness and are capable of ensuring high reliability.

### CROSS-REFERENCE TO RELATED APPLICATION

This application claims priority under 35 USC 119 from Japanese Patent Application No. 2006-221379, the disclosure of which is incorporated by reference herein.

### BACKGROUND OF THE INVENTION

1. Field of the Invention

The present invention relates to a semiconductor device and a semiconductor device fabrication method.

2. Description of the Related Art

Conventionally, in metal wires including via wires, it has been common primarily for copper (Cu) to be used from the standpoints of cost and conductivity. In methods of forming metal wires using copper, a step of using a sputtering method, for example, to sequentially form a barrier metal layer and a seed layer of copper (also called a glue film; this will simply be called a copper seed layer below) and forming a copper film on the copper seed layer by an electrolytic plating method has been used.

Yet when a copper wire is formed inside a via hole, for example, using the above method, sometimes the copper seed layer formed using the sputtering method has an overhanging shape where it projects out at the open portion of the via hole. When the copper seed layer has an overhanging shape in this manner, sometimes this can cause a problem where the open portion of the via hole becomes blocked by the copper seed layer and the copper seed layer is not formed in the bottom portion of the via hole. Because of this problem, sometimes a copper embedding defect occurs where the copper layer is not formed in the bottom portion of the via hole during electrolytic plating; as a result, problems such as defective connection occur.

As a method of solving this problem, it is conceivable to form the copper seed layer using an ionized sputtering method where the directivity of the sputtered electrons is high, for example.

However, these days, when miniaturization of via diameters and trench widths is demanded together with miniaturization of semiconductor devices, the copper ions cannot be sufficiently caused to reach the via hole and the bottom portions and side wall portions of the trench even when the ionized sputtering method is used, and sometimes a problem occurs where an extremely thin copper seed layer ends up being formed. When the thickness of the copper seed layer is insufficient in this manner, the copper dissolves out during electrolytic plating, a portion where there is no copper seed layer occurs at this portion and, as a result, a copper embedding defect occurs where the copper layer is not formed in the bottom portions of the via hole and trench; as a result, problems such as defective connection occur.

As a method of solving the above problem, in recent years, forming the copper seed layer using the chemical layer deposition (CVD) method and the atomic layer deposition (ALD) method, which with high coatability is obtained, for example, has been considered.

However, in methods of forming a copper seed layer using the CVD method and the ALD method, there are problems in terms of adhesiveness with the glue film and nucleation because fluorine is included in the film serving as a precursor. Thus, conventionally, methods of forming a copper film using the electrolytic plating method without forming a copper seed layer have been considered.

In methods of forming a copper film by the electrolytic plating method without using a copper seed layer, using ruthenium (Ru) and tungsten (W) in the glue film are being proposed. It is possible to directly deposit copper on a ruthenium film and a tungsten film by the electrolytic plating method, which is promising as a glue film candidate. Further, in addition to this, techniques for directly forming a copper film on tantalum nitride (TaN) by the electrolytic plating method are also being proposed.

Ruthenium (Ru), tungsten (W) and tantalum nitride (TaN) have the advantage that they do not cause the aforementioned problem even when a glue film whose material comprises any of these is thin, because there is no concern that they will dissolve out into the plating solution during electrolytic plating. Further, a film whose material comprises ruthenium (Ru), tungsten (W) or tantalum nitride (TaN) is capable of being formed using a thin film forming method such as the ALD method or the like, so even when the via hole and the trench have been miniaturized, there is also the advantage that the film can be formed evenly as far as the insides of these.

Further, among the above materials, ruthenium (Ru) in particular has an excellent barrier property with respect to copper. For this reason, it is also possible to use a film resulting from ruthenium as an alternative to a barrier film formed by a common barrier metal such as tantalum nitride (TaN) (e.g., see JP-A No. 10-229084). That is, the need to form a laminate film of a barrier film and a glue film can be eliminated by using, for the glue film, a ruthenium film whose barrier property with respect to copper is excellent.

However, when ruthenium (Ru), tungsten (W) or tantalum nitride (TaN) is used for the glue film, there is the problem that adhesiveness at the boundary surface between this film and the copper film formed by the electrolytic plating method is poor.

When adhesiveness at the boundary surface is poor in this manner, then a problem occurs where electromigration (EM) resistance and stress migration resistance of the copper film that is the main portion of the wire drop and, as a result, reliability drops.

### SUMMARY OF THE INVENTION

The present invention has been made in view of the above problems, and it is an object thereof to provide a semiconductor device and a semiconductor device fabrication method that have excellent adhesiveness and are capable of ensuring high reliability.

In order to achieve this object, a semiconductor device according to the present invention is configured to include: a semiconductor substrate; an insulation film that is formed on the semiconductor substrate and includes grooves; a glue film formed inside the grooves; and a metal plating film that is formed on a side surface of the glue film, includes a region having a first metal in a surface that contacts the glue film, and is formed by a second metal.

Further, a semiconductor device fabrication method according to the present invention is configured to include: forming an insulation film on a semiconductor substrate; forming grooves in the insulation film; forming a metal film including a first metal inside the grooves and on the insulation film; forming a glue film on the metal film; forming, on the glue film by an electrolytic plating method, a metal plating film that completely fills the grooves and comprises a second metal; evenly polishing the metal plating film, the glue film and the metal film from above to expose an upper surface of the insulation film and form wires comprising the metal plating film, the glue film and the metal film inside the grooves; and thermally processing the wires to cause the first metal to diffuse from the metal film to the metal plating film to form a region having the first metal in a surface of the metal plating film that contacts the glue film.

Further, a semiconductor device fabrication method according to the present invention is configured to include: forming an insulation film on a semiconductor substrate; forming grooves in the insulation film; forming a glue film having a first metal inside the grooves and on the insulation film; forming, on the glue film by an electrolytic plating method, a metal plating film that completely fills the grooves and comprises a second metal; evenly polishing the metal plating film and the glue film from above to expose an upper surface of the insulation film and form wires comprising the metal plating film and the glue film inside the grooves; and thermally processing the wires to cause the first metal to diffuse from the glue film to the metal plating film to form a region having the first metal in a surface of the metal plating film that contacts the glue film.

According to the present invention, it becomes possible to realize a semiconductor device and a semiconductor device fabrication method that have excellent adhesiveness and are capable of ensuring high reliability.

### BRIEF DESCRIPTION OF THE DRAWINGS

Preferred exemplary embodiments of the present invention will be described in detail based on the following figures, wherein:

FIG. 1 is a cross-sectional diagram showing the layer structure of a semiconductor device according to a first exemplary embodiment of the present invention;

FIG. 2A is a process diagram showing a method of fabricating the semiconductor device according to the first exemplary embodiment of the present invention;

FIG. 2B is a process diagram showing the method of fabricating the semiconductor device according to the first exemplary embodiment of the present invention;

FIG. 2C is a process diagram showing the method of fabricating the semiconductor device according to the first exemplary embodiment of the present invention;

FIG. 2D is a process diagram showing the method of fabricating the semiconductor device according to the first exemplary embodiment of the present invention;

FIG. 2E is a process diagram showing the method of fabricating the semiconductor device according to the first exemplary embodiment of the present invention;

FIG. 2F is a process diagram showing the method of fabricating the semiconductor device according to the first exemplary embodiment of the present invention;

FIG. 2G is a process diagram showing the method of fabricating the semiconductor device according to the first exemplary embodiment of the present invention;

FIG. 2H is a process diagram showing the method of fabricating the semiconductor device according to the first exemplary embodiment of the present invention;

FIG. 2I is a process diagram showing the method of fabricating the semiconductor device according to the first exemplary embodiment of the present invention;

FIG. 3 is an enlarged diagram of region A (FIG. 1) when the semiconductor device according to the first exemplary embodiment of the present invention includes a structure where glue films and doping material films are alternately plurally laminated;

FIG. 4 is a cross-sectional diagram showing the layer structure of a semiconductor device according to a second exemplary embodiment of the present invention;

FIG. 5A is a process diagram showing a method of fabricating the semiconductor device according to the second exemplary embodiment of the present invention;

FIG. 5B is a process diagram showing the method of fabricating the semiconductor device according to the second exemplary embodiment of the present invention;

FIG. 5C is a process diagram showing the method of fabricating the semiconductor device according to the second exemplary embodiment of the present invention;

FIG. 5D is a process diagram showing the method of fabricating the semiconductor device according to the second exemplary embodiment of the present invention;

FIG. 5E is a process diagram showing the method of fabricating the semiconductor device according to the second exemplary embodiment of the present invention;

FIG. 6 is a cross-sectional diagram showing the layer structure of a semiconductor device according to a third exemplary embodiment of the present invention;

FIG. 7A is a process diagram showing a method of fabricating the semiconductor device according to the third exemplary embodiment of the present invention;

FIG. 7B is a process diagram showing the method of fabricating the semiconductor device according to the third exemplary embodiment of the present invention;

FIG. 7C is a process diagram showing the method of fabricating the semiconductor device according to the third exemplary embodiment of the present invention;

FIG. 7D is a process diagram showing the method of fabricating the semiconductor device according to the third exemplary embodiment of the present invention;

FIG. 7E is a process diagram showing the method of fabricating the semiconductor device according to the third exemplary embodiment of the present invention;

FIG. 7F is a process diagram showing the method of fabricating the semiconductor device according to the third exemplary embodiment of the present invention;

FIG. 8 is a cross-sectional diagram showing the layer structure of a semiconductor device according to a fourth exemplary embodiment of the present invention;

FIG. 9A is a process diagram showing a method of fabricating the semiconductor device according to the fourth exemplary embodiment of the present invention;

FIG. 9B is a process diagram showing the method of fabricating the semiconductor device according to the fourth exemplary embodiment of the present invention;

FIG. 9C is a process diagram showing the method of fabricating the semiconductor device according to the fourth exemplary embodiment of the present invention;

FIG. 9D is a process diagram showing the method of fabricating the semiconductor device according to the fourth exemplary embodiment of the present invention; and

FIG. 9E is a process diagram showing the method of fabricating the semiconductor device according to the fourth exemplary embodiment of the present invention.

### DETAILED DESCRIPTION OF THE INVENTION

The best modes for implementing the present invention will be described in detail below together with the drawings. In the description below, the drawings are intended only to generally show shapes, sizes and positional relationships to the extent that the content of the present invention can be understood; consequently, the present invention is not limited to the shapes, sizes and positional relationships shown in the drawings. Further, in the drawings, some of the hatching in the cross sections is omitted in order to clarify configurations. Moreover, numerical values exemplarily described below are only preferred examples of the present invention; consequently, the present invention is not limited to the exemplarily described numerical values.

### First Exemplary Embodiment

First, the configuration and method of fabricating a semiconductor device 1 according to a first exemplary embodiment of the present invention will be described in detail using the drawings.

### Configuration

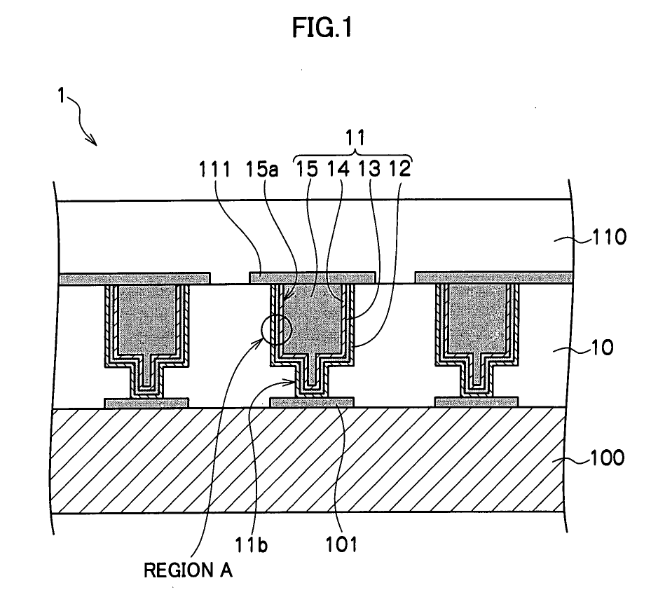

FIG. 1 is a cross-sectional diagram showing the configuration of the semiconductor device 1 according to the present exemplary embodiment. The cross-sectional diagram shown in FIG. 1 is a diagram when the semiconductor device 1 is cut along a plane that is perpendicular to the surface of a semiconductor substrate 100.

As shown in FIG. 1, the semiconductor device 1 includes a semiconductor substrate 100, a first insulation film 10, a second insulation film 110, first wires 101, second wires 11, and third wires 111.

The semiconductor substrate 100 is a silicon substrate, for example. However, the semiconductor substrate 100 is not limited to this, and various substrates can be applied, such as a compound semiconductor substrate or a piezoelectric substrate. Further, elements (not shown) such as transistors, capacitors and resistor elements are formed on the semiconductor substrate 100.

A conductor pattern including unillustrated wires and the first wires 101 electrically connected via unillustrated wires to the elements formed on the semiconductor substrate 100 is formed on the semiconductor substrate 100. The conductor pattern is a conductor layer formed by copper and aluminium.

The first insulation film 10 formed on the semiconductor substrate 100 is an insulation film formed by depositing an insulator such as silicon dioxide, for example.

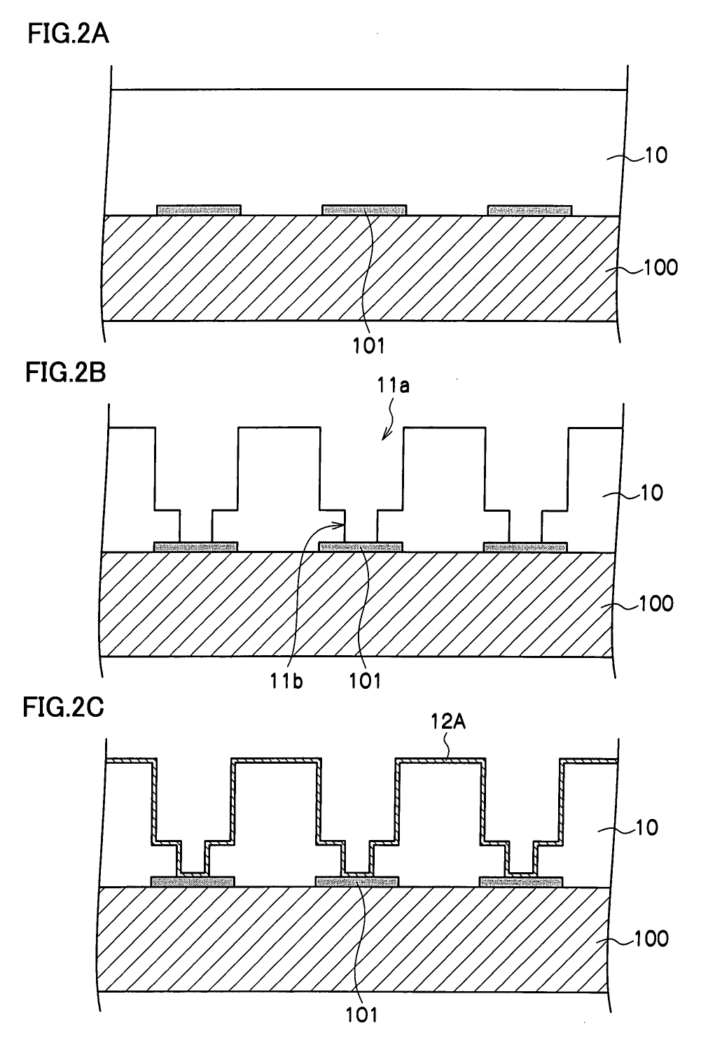

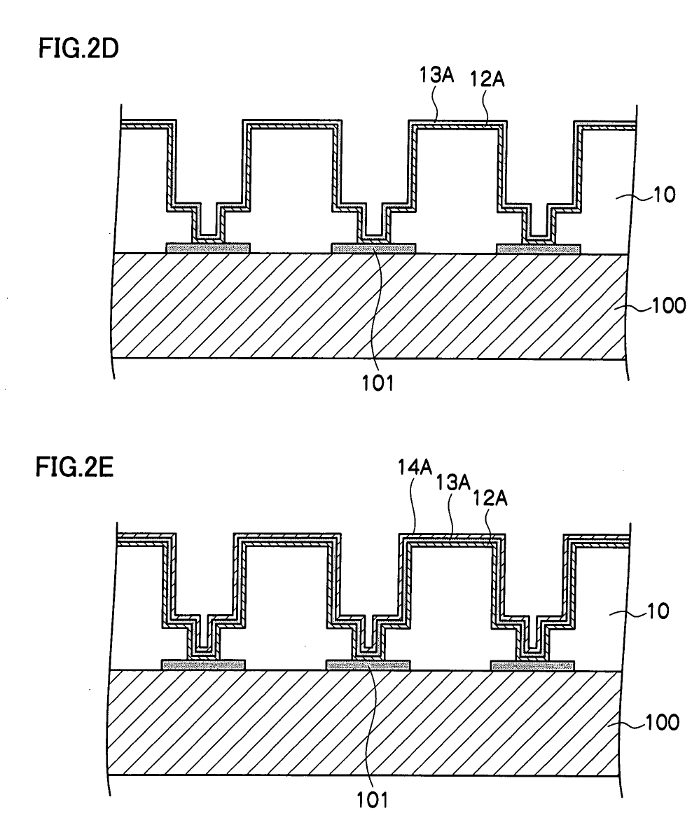

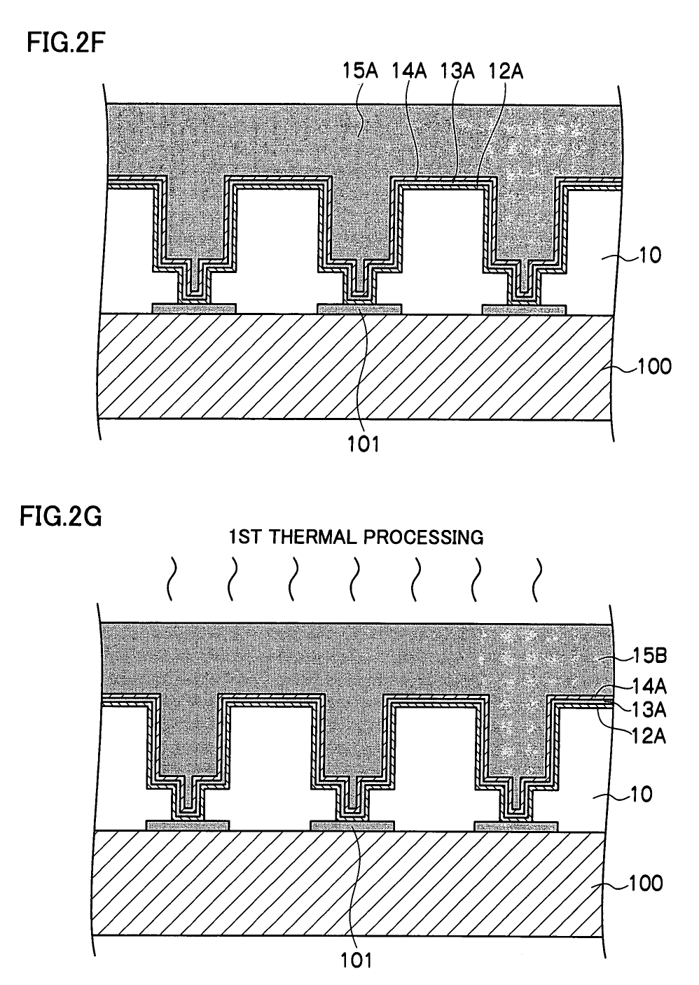

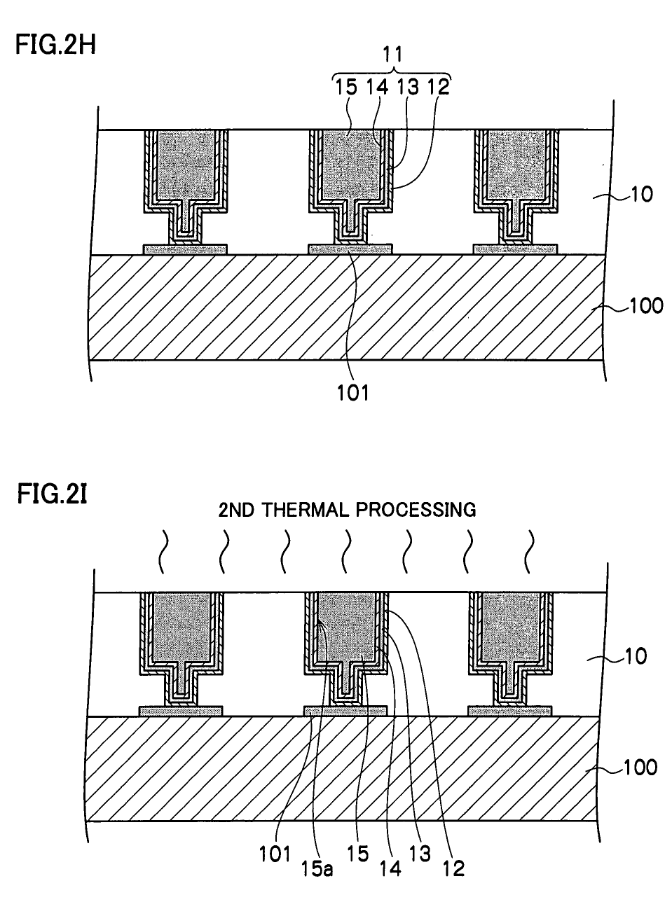

Grooves 11a and through holes (see FIG. 2B), for example, are formed in the first insulation film 10, and the second wires 11 are formed inside these. Each of the second wires 11 comprises a barrier film 12, a doping material film 13, a glue film 14 and a copper plating film 15. The depth of the grooves 11a in which the second wires 11 are formed can be about 0.3 μm (micrometers), for example. The width of the grooves 11a in which the second wires 11 are formed can be about 0.2 μm, for example. Through holes 11b whose open shape is circular, for example, are formed in the bottoms of the grooves 11a. The through holes 11b allow part of the first wires 101 to be exposed. Consequently, the second wires 11 formed inside the grooves 11a and the through holes 11b are electrically connected to the first wires 101. The diameter of the open shapes of the through holes 11b can be about 0.2 μm, and the depth of the through holes 11b can be about 0.3 μm, for example. However, the dimensions are not limited to these, and various dimensions can be applied.

Of the layers configuring each of the second wires 11, the barrier film 12 is a diffusion preventing layer for preventing the metal atoms configuring the layers formed on the barrier film 12—such as the doping material film 13, the glue film 14 and the copper plating film 15—from spreading to the first insulation film 10. However, the barrier film 12 is a conductor film. Tantalum nitride (TaN), for example, can be applied for the barrier film 12. However, the barrier film 12 is not limited to this, and any material can be applied as long as the barrier film 12 is a film formed by a material that can prevent the diffusion of predetermined metal atoms and whose resistivity is sufficiently small—such as titanium silicon nitride (TiSiN), tungsten nitride (WN), and titanium nitride (TiN), for example. Further, the film thickness of the barrier film 12 can be about 20 nm (nanometers), for example.

The doping material film 13 is a conductor film configured by a material (called “doping material” below) including atoms to be diffused to the copper plating film 15. In the present exemplary embodiment, titanium (Ti) is used as the doping material and a titanium film is used as the doping material film 13. However, in the present invention, the doping material is not limited to this and any one or more of the following can also be used: lithium (Li), beryllium (Be), boron (B), magnesium (Mg), aluminium (Al), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb). Further, the film thickness of the doping material film 13 can be about 10 nm, for example.

The glue film 14 is a conductor film serving as a seed layer when forming the copper plating layer 15 using an electrolytic plating method. In the present exemplary embodiment, a ruthenium (Ru) film is given as an example of the glue film 14. However, in the present invention, the glue film 14 is not limited to this and a tungsten (W) film or the like, for example, can also be used as the glue film 14. Further, the film thickness of the glue film 14 can be about 10 nm, for example.

The copper plating film 15 is a conductor film formed by an electrolytic plating method using the glue film 14 as a seed layer as mentioned above. A region (called a “doping material-including conductive layer 15a” below) including doping material (in the present example, titanium (Ti) atoms) that has been thermally diffused from the doping material film 13 is formed in the surface of the copper plating film 15 that contacts the glue film 14. The doping material-including conductive layer 15a is a layer for forming a reaction layer on, the contact surface between the copper plating film 15 and the glue film 14. In this manner, it becomes possible to strengthen one or both of the physical bonding force resulting from the anchor effect by forming concavo-convexities in the contact surface between the copper plating film 15 and the glue film 14 and the chemical bonding force by forming a reaction layer. As a result, it becomes possible to improve the adhesive force between the copper plating film 15 and the glue film 14. That is, by forming the doping material-including conductive layer 15a at the boundary surface between the copper plating film 15 and the glue film 14 as in the present exemplary embodiment, it becomes possible to improve the adhesiveness between the copper plating film 15 and the glue film 14 when a ruthenium film is used as the glue film 14.

Further, a conductor pattern including unillustrated wires and the third wires 111 electrically connected to the second wires 11 is formed on the first insulation film 10 on which the second wires 11 have been formed. The conductor pattern is, similar to that of the first wires 101, a conductor layer formed by copper and aluminium.

Further, the second insulation film 110 is formed on the first insulation film 10 on which the conductor pattern including the third wires 111 has been formed. The second insulation film 110 is an insulation film formed by silicon dioxide, silicon nitride, or an insulating resin, for example.

### Fabrication Method

Next, a method of fabricating the semiconductor device 1 including the above configuration will be described in detail together with the drawings. FIG. 2A to FIG. 2I are process diagrams showing the method of fabricating the semiconductor device 1 according to the present exemplary embodiment.

In the present fabrication method, first, the semiconductor substrate 100 on which elements such as transistors, capacitors and resistors have been formed is prepared. Next, a conductor film comprising copper and aluminium is formed on the semiconductor substrate 100, and this is worked using publicly known photolithographic techniques and etching techniques, whereby a conductor pattern including the first wires 101 is formed on the semiconductor substrate 100. Next, an insulator such as silicon dioxide is deposited on the semiconductor substrate 100 using the chemical vapor deposition (CVD) method, for example, whereby the first insulation film 10 is formed. Thus, the layer structure shown in FIG. 2A is obtained.

Next, the first insulation film 10 formed on the semiconductor substrate 100 is worked using publicly known photolithographic techniques and etching techniques, whereby the grooves 11a whose width is 0.2 μm and whose depth is 0.3 μm, for example, are formed in the first insulation film 10. Next, the first insulation film 10 in the bottom portions of the grooves 11a is similarly worked using publicly known photolithographic techniques and etching techniques, whereby the through holes 11b whose open shape diameters are 0.2 μm and whose depth is 0.3 μm, for example, are formed as shown in FIG. 2B.

Next, tantalum nitride (TaN) is deposited using the sputtering method, for example, whereby a barrier film 12A comprising a tantalum nitride film whose film thickness is about 20 nm, for example, is formed on the first insulation film 10 and inside the grooves 11a and the through holes 11b as shown in FIG. 2C. In the film forming conditions at this time, tantalum (Ta) can be used as the target, a mixed gas of Ar and N₂ can be used as the process gas, the gas flow ratio of Ar/N₂ can be equal to about 28/72 sccm, the pressure of the sputtering atmosphere can be 3.5 mTorr (milliTorr), the DC power can be 700 W (Watts), and the film forming temperature can be 150° C. However, in addition to the sputtering method mentioned above, various film forming methods can be applied as the method of forming the barrier film 12A—such as the CVD method using penta(dimethylamino)tantalum (PDMAT), Ar, or NH₃.

Next, titanium (Ti) is deposited using the plasma CVD method, for example, whereby a doping material film 13A comprising a titanium film whose film thickness is about 10 nm, for example, is formed on the barrier film 12A as shown in FIG. 2D. In the film forming conditions at this time, TiCl₄ can be used as the raw material gas, H₂ can be used as the reducing gas, and the substrate temperature can be 400 to 450° C. However, as mentioned above, in addition to titanium (Ti), any one or more of the following can also be applied as the doping material: lithium (Li), beryllium (Be), boron (B), magnesium (Mg), aluminium (Al), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb).

Next, ruthenium (Ru) is deposited using the ALD method, for example, whereby a glue film 14A comprising a ruthenium film whose film thickness is about 10 nm, for example, is formed on the doping material film 13A as shown in FIG. 2E. In the film forming conditions at this time, RuCp2 (Cp=cyclopentadienyl) can be used as the metal precursor, O2 can be used as the reaction gas, and the substrate temperature can be about 300 to 400° C. However, in addition to ruthenium (Ru), tungsten (W) or the like, for example, can also be applied as the material of the glue film 14A when forming a copper plating film 15A (see FIG. 2F) by the electrolytic plating method.

In the above description, an example is given where the CVD method (the ALD method) is used to form the doping material film 13A and the glue film 14A, but the present invention is not limited to this; various film forming methods such as the sputtering method can also be applied. For example, when a ruthenium film is used as the glue film 14A, there is no concern that the ruthenium film will dissolve out into the plating solution during electrolytic plating as with a seed layer made of copper. For this reason, the film thickness of the glue film 14A is optimized (thinned), so that it is possible to form a ruthenium film to be used as the glue film even with a film forming method such as the sputtering method where conformal growth is difficult. Further, similar to the glue film 14A, the film thickness of the doping material film 13A that does not directly contact the plating solution during electrolytic plating can be optimized (thinned), so that it is possible to form the doping material film 13A using a film forming method such as the sputtering method.

As described above, when the laminate film comprising the barrier film 12A, the doping material film 13A and the glue film 14A is formed, next, the electrolytic plating method is used, whereby, as shown in FIG. 2F, a copper plating film 15A that completely fills the grooves 11a and the through holes 11b formed in the first insulation film 10 is formed on the glue film 14A. Because it is possible to use publicly known conditions in the electrolytic plating method at this time, detailed description will be omitted here.

Next, as shown in FIG. 2G, thermal processing is administered to the copper plating film 15A formed by the electrolytic plating method. Thus, the copper plating film 15A changes in nature to a copper plating film 15B. In the description below, this thermal processing will be referred to first thermal processing. The first thermal processing is processing whose purpose is to stabilize the layer qualities—such as strength, crystallinity and resistivity—of the copper plating film 15A. In the conditions at this time, the thermal processing temperature (this will be called a first temperature) can be about 100 to 350° C., the processing time can be about 1 to 5 hours, and a mixed gas of N₂ and H₂ can be used as the atmosphere inside the chamber. It is preferable to variously change these conditions depending on various factors such as the width of the second wires 11 and the film thicknesses of the layers configuring these. However, in the present exemplary embodiment, it is preferable to reduce as much as possible the doping material (in the present example, titanium (Ti)) that is thermally diffused from the doping material film 13A to the copper plating film 15A by the first thermal processing. For this reason, in the present exemplary embodiment, the first temperature is a temperature sufficiently lower than the temperature at which thermal diffusion of the doping material is efficiently performed. Further, in the first thermal processing, it is preferable for the processing time to be a relatively long amount of time in order to sufficiently grow the crystal grains of the copper in the copper plating film 15A formed by the electrolytic plating method.

When the copper plating film 15B that fills the grooves 11a and the through holes 11b in the first insulation film 10 is formed as described above, next, the copper plating film 15B, the glue film 14A, the doping material film 13A and the barrier film 12A are sequentially polished using the chemical and mechanical polishing (CMP) method, for example, until the upper surface of the first insulation film 10 is exposed. Thus, as shown in FIG. 2H, each of the conductor layers (12A, 13A, 14A, 15B) on the first insulation film 10 is removed while the second wires 11 comprising the barrier film 12, the doping material film 13, the glue film 14 and the copper plating film 15 remain inside the grooves 11a and the through holes 11b.

For the polishing at this time, an existing chemical mechanical polishing (CMP) apparatus can be used where independent pressurization control mechanisms are disposed in a carrier (mechanism for holding a wafer that is the polishing target), a retainer ring (mechanism for holding the wafer that is the polishing target) and the underside of the wafer, and where independent rotation mechanisms are disposed in the carrier and a platen (abrasive cloth for polishing the wafer held in the carrier). Further, in the conditions during polishing, a silica-based slurry in which hydrogen peroxide (H₂O₂) is mixed as an oxidizing agent can be used as the slurry, the down force (pressurizing force) of the carrier can be about 2.5 psi, the back pressure on the underside of the wafer can be about 1 psi, the down force of the retainer ring can be about 2.5 psi, the rotational speed of the carrier can be about 80 rpm, and the rotational speed of the platen can be about 80 rpm, for example.

Moreover, in the present exemplary embodiment, the copper plating film 15B, the glue film 14A, the doping material film 13A and the barrier film 12A are sequentially polished using a polishing step comprising two steps. In the first polishing step, just the copper plating film 15B is polished. Consequently, as a result of the first polishing step, the layers positioned below the uppermost surface of the glue film 14A—that is, the glue film 14A, the doping film 13A, the barrier film 12A and part of the copper plating film 15B—remain. In the second polishing step, the glue film 14A, the doping material film 13A, the barrier film 12A and part of the copper plating film 15B that are above the uppermost surface of the first insulation film 10 are removed using another slurry than the slurry used in the first polishing step. Thus, the conductor layers (12A, 13A, 14A, 15B) above the uppermost surface of the exposed first insulation film 10 are completely removed such that the upper surface of the first insulation film 10 is exposed, and the second wires 11 comprising the barrier film 12, the doping material film 13, the glue film 14 and the copper plating film 15 are formed inside the grooves 11a and the through holes 11b formed in the first insulation film 10.

Next, thermal processing is administered to the second wires 11 remaining inside the grooves 11a and the through holes 11b. Thus, as shown in FIG. 2I, the doping material (in the present example, titanium (Ti) atoms) in the doping material film 13 diffuses to the copper plating film 15 via the glue film 14, and a copper plating film including the doping material (the doping material-including conductive layer 15a) is formed at the boundary surface between the copper plating film 15 and the glue film 14. In the description below, this thermal processing will be referred to as second thermal processing. The second thermal processing is a step for causing the atoms of the doping material film 13 to diffuse to the copper plating film 15 as mentioned above. For this reason, it is preferable for the thermal processing temperature (this will be called a second temperature) in the second thermal processing to be equal to or greater than the temperature at which thermal diffusion of the doping material is efficiently performed. For this reason, the second temperature is set to a higher temperature than the first temperature used in the first thermal processing, for example. Here, when titanium (Ti) is used as the doping material, for example, then the second temperature is set within the range of about 250 to 450° C. (e.g., 400° C.), for example. However, the second temperature is not limited to the aforementioned temperature range, and it is preferable for the second temperature to be variously changed depending on the type of atoms used in the doping material.

When the doping material-including conductive layer 15a is formed as described above, next, a conductor film comprising copper and aluminium is formed on the first insulation film 10 on which the second wires 11 have been formed, and this is worked using publicly known photolithographic techniques and etching techniques, whereby a conductor pattern including the third wires 111 is formed on the first insulation film 10. Next, an insulator such as silicon dioxide is deposited on the first insulation film 10 by the CVD method, for example, whereby the second insulation film 110 is formed. Thus, the semiconductor device 1 shown in FIG. 1 is fabricated.

As described above, the semiconductor device 1 according to the present exemplary embodiment is configured to include: the semiconductor substrate 100; the first insulation film 10 that is formed on the semiconductor substrate 100 and includes the grooves 11a (also including the through holes 11b); the glue film 14 formed inside the grooves 11a; and a metal plating film (the copper plating film 15) that is formed on a side surface of the glue film 14, includes a region (the doping material-including conductive layer 15a) having a first metal (e.g., titanium) in a surface that contacts the glue film 14, and is formed by a second metal (e.g., copper).

As mentioned above, the film formed by any one or more of ruthenium (Ru) and tungsten (W), for example, is a film capable of functioning as a seed layer (the glue film 14) when depositing the second metal such as copper by the electrolytic plating method. Further, the glue film 14 formed by any one or more of these can be formed using a thin film forming method such as the ALD method, for example. For this reason, using a film formed by any one or more of ruthenium (Ru) and tungsten (W) as the glue film 14 during electrolytic plating becomes advantageous when forming the second wires 11 comprising a metal plating film (e.g., the copper plating film 15) inside the grooves 11a and the through holes 11b whose aspect ratio is large. Further, by disposing a region (the doping material-including layer 15a) where the first metal (e.g., titanium) that is different from the second metal (e.g., copper) is included in the surface of the metal plating film (e.g., the copper plating film 15) that contacts the glue film 14, concavo-convexities are formed in, or a reaction layer is formed on, the contact surface between the metal plating film (e.g., the copper plating film 15) and the glue film 14. For this reason, it becomes possible to strengthen one or both of the physical bonding force resulting from the anchor effect by forming concavo-convexities and the chemical bonding force by forming a reaction layer. That is, it becomes possible to realize the semiconductor device 1 that has excellent adhesiveness and is capable of ensuring high reliability. Moreover, by disposing, between the first insulation film 10 on which the second wires 11 are formed and the metal plating film (e.g., the copper plating film 15), a diffusion barrier film (the barrier film 12) capable of preventing diffusion of the second metal (e.g., copper) to the first insulation film 10, it becomes possible to more reliably prevent the second metal (e.g., copper) from diffusing from the metal plating film (e.g., the copper plating film 15) to the first insulation film 10.

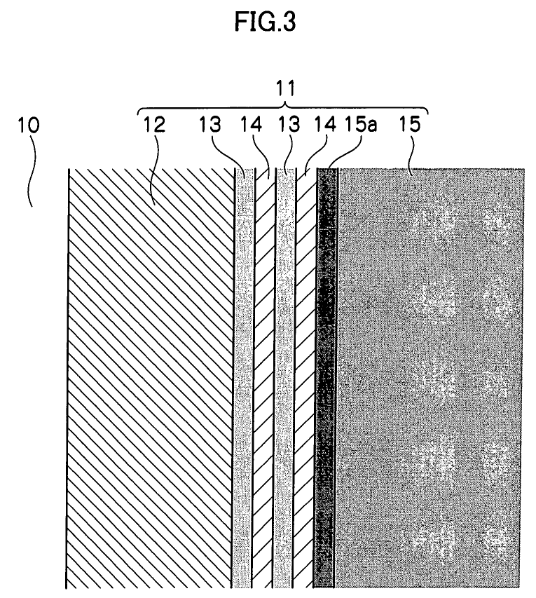

In the above-described first exemplary embodiment, an example was given where a single layer of each of the doping material film 13 and the glue film 14 was formed between the barrier film 12 and the copper plating film 15. However, the present invention is not limited to this. For example, as shown in FIG. 3, a laminate film comprising the doping material film 13 and the glue film 14 may also be formed in plural layers (in the present example, two layers) between the barrier film 12 and the copper plating film 15. That is, the semiconductor device 1 according to the present exemplary embodiment may also include a configuration where the glue film 14 and the doping material film 13 are alternately plurally laminated. The enlarged diagram shown in FIG. 3 is an enlarged diagram of region A (see FIG. 1) when the semiconductor device 1 includes a configuration where the glue film 14 and the doping material film 13 are alternately plurally laminated. The fabrication method in this case is as follows.

That is, first, the barrier film 12A is formed on the first insulation film 10 and inside the grooves 11a and the through holes 11b using the steps described using FIG. 2A to FIG. 2C in the above description. Next, ruthenium (however, the other materials mentioned above can also be applied) is deposited using the ALD method, for example, whereby a thin ruthenium film (thin glue film 14A) is formed on the barrier film 12A. In the film forming conditions at this time, RuCp2 (Cp=cyclopentadienyl) can be used as a metal precursor, O₂ can be used as the reaction gas, and the substrate temperature can be about 200 to 350° C. Next, aluminium (however, the other materials mentioned above can also be applied) is deposited using the CVD method, for example, whereby a thin aluminium film (thin doping film 13A) is formed on the ruthenium film formed as mentioned above. In the film forming conditions at this time, AlH(CH₃)₂ can be used as the material gas and H₂ can be used as the reaction gas, for example. The thin ruthenium film and aluminium film can be formed inside the same chamber. Thereafter, the thin ruthenium film and the thin aluminium film are alternately formed in plural layers, whereby a laminate film whose total film thickness is about 10 nm, for example, is formed. Thereafter, the copper plating film 15A is formed using the step shown in FIG. 2F, and thereafter the semiconductor device 1 is fabricated using the steps described using FIG. 2G to FIG. 2I and FIG. 1.

### Second Exemplary Embodiment

Next, a second exemplary embodiment of the present invention will be described in detail using the drawings. In the description below, configurations that are the same as those of the first exemplary embodiment will be given the same reference numerals and detailed description of those configurations will be omitted. Further, configurations not specifically mentioned are the same as those of the first exemplary embodiment.

### Configuration

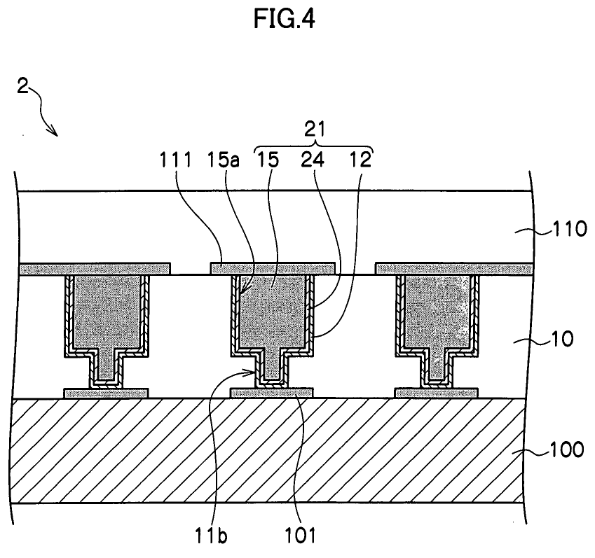

FIG. 4 is a cross-sectional diagram showing the configuration of a semiconductor device 2 according to the present exemplary embodiment. The cross-sectional diagram shown in FIG. 4 is a diagram when the semiconductor device 2 is cut along a plane that is perpendicular to the surface of the semiconductor substrate 100.

As shown in FIG. 4, the semiconductor device 2 includes a configuration where, in a configuration that is the same as that of the semiconductor device 1 according to the first exemplary embodiment, the second wires 11 are replaced by second wires 21.

The second wires 21 include a configuration where, in a configuration that is the same as that of the second wires 11 according to the first exemplary embodiment, the glue film 14 is replaced by a doping material-including glue film 24 and the doping material film 13 is omitted.

The doping material-including glue film 24 of the second wires 21 is a layer that functions as a seed layer during electrolytic plating and is a layer that includes the doping material of the first exemplary embodiment. That is, the doping material-including glue film 24 realizes the functions of both the doping material film 13 and the glue film 14 of the first exemplary embodiment. For this reason, in the present exemplary embodiment, the doping material film 13 of the second wires 11 is omitted and the glue film 14 is replaced by the doping material-including glue film 24.

Similar to the glue film 14 of the first exemplary embodiment, ruthenium, for example, can be used for the main configural material of the doping material-including glue film 24. However, in the present invention, the main configural material of the doping material-including glue film 24 is not limited to this and a tungsten (W) film or the like, for example, can also be used. Further, the film thickness of the doping material-including glue film 24 can be about 10 nm, for example.

As the doping material included in the doping material-including glue film 24, titanium (Ti), for example, can be used. However, in the present invention, the doping material is not limited to this and, similar to the first exemplary embodiment, any one or more of the following can also be used: lithium (Li), beryllium (Be), boron (B), magnesium (Mg), aluminium (Al), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb). Further, the concentration of the doping material in the doping material-including glue film 24 is variously changed depending on the doping material (in the present example, titanium) to be diffused to the copper plating film 15. In the present exemplary embodiment, the added amount of the doping material is about 0.1 to 10 at %, for example.

The doping material-including glue film 24 is a single layer film with a configuration where the doping material (in the present example, titanium) is included in the material (in the present example, ruthenium) functioning as the glue film.

The remaining configurations are the same as those of the semiconductor device 1 according to the first exemplary embodiment, so detailed description thereof will be omitted here.

### Fabrication Method

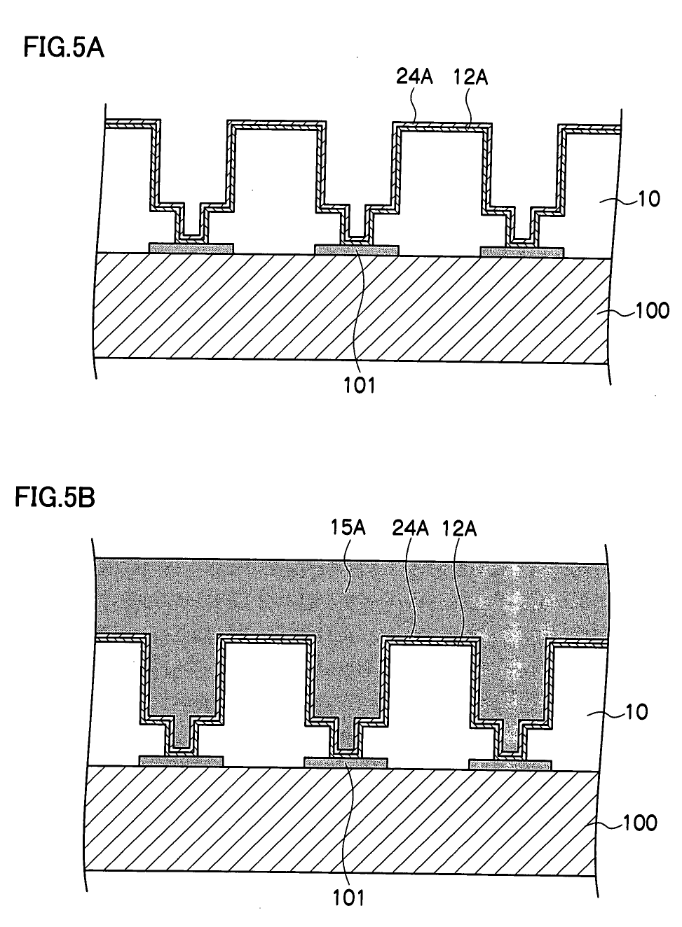

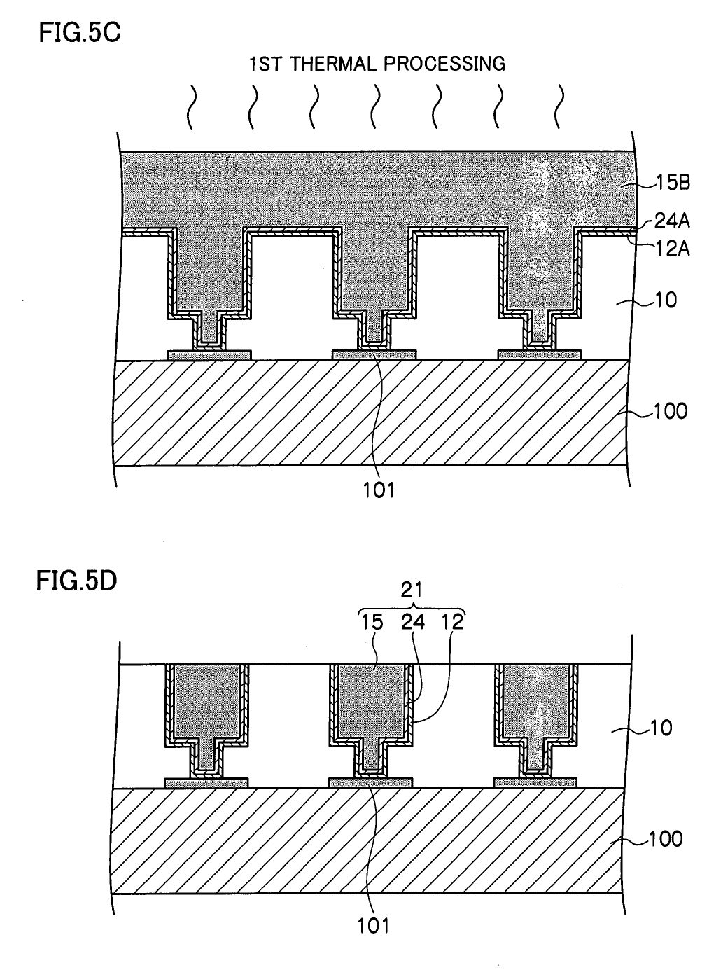

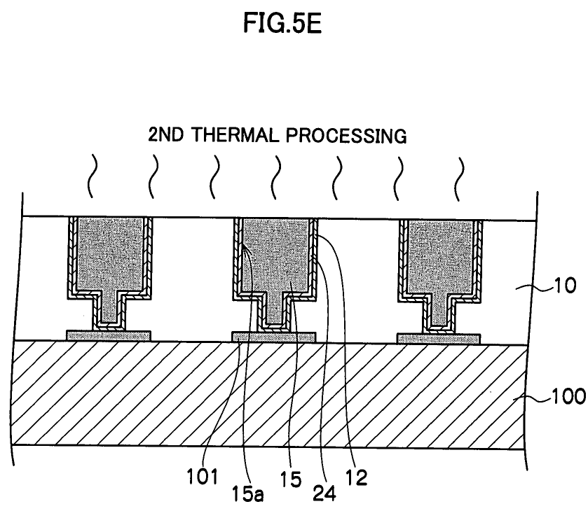

Next, a method of fabricating the semiconductor device 2 including the above configuration will be described in detail together with the drawings. FIG. 5A to FIG. 5E are process diagrams showing the method of fabricating the semiconductor device 2 according to the present exemplary embodiment. The steps shown in FIG. 2A to FIG. 2C of the first exemplary embodiment are also the same in the present exemplary embodiment, so they will be quoted and described here.

In the present fabrication method, first, the semiconductor substrate 100 on which elements such as transistors, capacitors and resistors have been formed is prepared. Next, a conductor film comprising copper and aluminium is formed on the semiconductor substrate 100, and this is worked using publicly known photolithographic techniques and etching techniques, whereby a conductor pattern including the first wires 101 is formed on the semiconductor substrate 100. Next, an insulator such as silicon dioxide is deposited on the semiconductor substrate 100 using the CVD method, for example, whereby the first insulation film 10 is formed. Thus, the layer structure shown in FIG. 2A is obtained.

Next, the first insulation film 10 formed on the semiconductor substrate 100 is worked using publicly known photolithographic techniques and etching techniques, whereby the grooves 11a whose width is 0.2 μm and whose depth is 0.3 μm, for example, are formed in the first insulation film 10. Next, the first insulation film 10 in the bottom portions of the grooves 11a is similarly worked using publicly known photolithographic techniques and etching techniques, whereby the through holes 11b whose open shape diameters are 0.2 μm and whose depth is 0.3 μm, for example, are formed as shown in FIG. 2B.

Next, tantalum nitride (TaN) is deposited using the sputtering method, for example, whereby a barrier film 12A comprising a tantalum nitride film whose film thickness is about 20 nm, for example, is formed on the first insulation film 10 and inside the grooves 11a and the through holes 11b as shown in FIG. 2C. In the film forming conditions at this time, tantalum (Ta) can be used as the target, a mixed gas of Ar and N₂ can be used as the process gas, the gas flow ratio of Ar/N₂ can be equal to about 28/72 sccm, the pressure of the sputtering atmosphere can be 3.5 mTorr (milliTorr), the DC power can be 700 W (Watts), and the film forming temperature can be 150° C. However, in addition to the sputtering method mentioned above, various film forming methods can be applied as the method of forming the barrier film 12A—such as the CVD method using penta(dimethylamino)tantalum (PDMAT), Ar, or NH₃.

The steps up to here are the same as those of the fabrication method in the first exemplary embodiment. In the present exemplary embodiment, next, ruthenium (Ru) and titanium (Ti) are deposited using the sputtering method, for example, whereby a ruthenium film including titanium (a doping material-including glue film 24A) is formed on the barrier film 12A. In the film forming conditions at this time, the pressure of the sputtering atmosphere can be about 2 mTorr, the DC power can be about 10 kW, and the film forming temperature can be about 30° C. As the material functioning as the glue film in the doping material-including glue film 24, tungsten (W) or the like, for example, can also be applied in addition to ruthenium (Ru). Further, in addition to titanium (Ti), any one or more of the following can also be applied as the doping material included therein: lithium (Li), beryllium (Be), boron (B), magnesium (Mg), aluminium (Al), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb). Because of this step, as shown in FIG. 5A, a doping material-including glue film 24A whose film thickness is about 10 nm is formed on the barrier film 12A.

In the above description, an example is given where the sputtering method is used to form the doping material-including glue film 24A, but the present invention is not limited to this; various film forming methods such as the CVD (ALD) method can also be applied.

As described above, when the laminate film comprising the barrier film 12A and the doping material-including glue film 24A is formed, next, the electrolytic plating method is used, whereby, as shown in FIG. 5B, a copper plating film 15A that completely fills the grooves 11a and the through holes 11b formed in the first insulation film 10 is formed on the doping material-including glue film 24A. Because it is possible to use publicly known conditions in the electrolytic plating method at this time, detailed description will be omitted here.

Next, as shown in FIG. 5C, first thermal processing is administered to the copper plating film 15A formed by the electrolytic plating method. Thus, the copper plating film 15A changes in nature to a copper plating film 15B. The first thermal processing is the same as that of the first exemplary embodiment, so detailed description will be omitted here.

Next, the copper plating film 15B, the doping material-including glue film 24A and the barrier film 12A are sequentially polished using the CMP method, for example, until the upper surface of the first insulation film 10 is exposed. Thus, as shown in FIG. 5D, the second wires 21 comprising the barrier film 12, each of the conductor layers (12A, 24A, 15B) on the first insulation film 10 is removed while the doping material-including glue film 24 and the copper plating film 15 remain inside the grooves 11a and the through holes 11b. Similar to the first exemplary embodiment, a polishing step comprising two steps can be used for the polishing at this time.

Next, second thermal processing is administered to the second wires 21 remaining inside the grooves 11a and the through holes 11b. Thus, as shown in FIG. 5E, the doping material (in the present example, titanium (Ti) atoms) in the doping material-including glue film 24 diffuses to the copper plating film 15 via the glue film 14a, and a copper plating film including the doping material (a doping material-including conductive layer 15a) is formed at the boundary surface between the copper plating film 15 and the glue film 14a. The second thermal processing is the same as that of the first exemplary embodiment, so detailed description will be omitted here. Further, in the case of a configuration where the glue film 14a is not formed, the doping material (in the present example, titanium (Ti)) thermally diffuses directly from the doping material-including glue film 24 to the copper plating film 15, and a copper plating film including the doping material (the doping material-including conductive layer 15a) is formed at the boundary surface between the copper plating film 15 and the doping material-including glue film 24.

When the doping material-including conductive layer 15a is formed as described above, next, a conductor film comprising copper and aluminium is formed on the first insulation film 10 on which the second wires 21 have been formed, and this is worked using publicly known photolithographic techniques and etching techniques, whereby a conductor pattern including the third wires 111 is formed on the first insulation film 10. Next, an insulator such as silicon dioxide is deposited on the first insulation film 10 by the CVD method, for example, whereby the second insulation film 110 is formed. Thus, the semiconductor device 2 shown in FIG. 4 is fabricated.

As described above, the semiconductor device 2 according to the present exemplary embodiment is configured to include: the semiconductor substrate 100; the first insulation film 10 that is formed on the semiconductor substrate 100 and includes the grooves 11a (including the through holes 11b); the doping material-including glue film 24 formed inside the grooves 11a; and a metal plating film (the copper plating film 15) that is formed on a side surface of the doping material-including glue film 24, includes a region (the doping material-including conductive layer 15a) having a first metal (e.g., titanium) in a surface that contacts the doping material-including glue film 24, and is formed by a second metal (e.g., copper).

As mentioned above, the film formed by any one or more of ruthenium (Ru) and tungsten (W), for example, is a film capable of functioning as a seed layer (the glue film 14) when depositing the second metal such as copper by the electrolytic plating method. Further, the glue film 14 formed by any one or more of these can be formed using a thin film forming method such as the ALD method, for example. For this reason, using a film formed by any one or more of ruthenium (Ru) and tungsten (W) as the glue film 14 during electrolytic plating becomes advantageous when forming the second wires 21 comprising a metal plating film (e.g., the copper plating film 15) inside the grooves 11a and the through holes 11b whose aspect ratio is large. Further, by disposing a region (the doping material-including layer 15a) where the first metal (e.g., titanium) that is different from the second metal (e.g., copper) is included in the surface of the metal plating film (e.g., the copper plating film 15) that contacts the glue film 14, concavo-convexities are formed in, or a reaction layer is formed on, the contact surface between the metal plating film (e.g., the copper plating film 15) and the glue film 14, so it becomes possible to strengthen one or both of the chemical bonding force and the physical bonding force resulting from the anchor effect. That is, it becomes possible to realize the semiconductor device 2 that has excellent adhesiveness and is capable of ensuring high reliability. Moreover, by configuring the semiconductor device such that the first metal (e.g., titanium) to be diffused to the metal plating film (e.g., the copper plating film 15) is included in the glue film (the doping material-including glue film 24), it becomes unnecessary to separately dispose a film including the first metal (e.g., titanium) that is used as the doping material, so it becomes possible to further simplify the configuration and fabrication method. Further still, by disposing, between the first insulation film 10 on which the second wires 21 are formed and the metal plating film (e.g., the copper plating film 15), a diffusion barrier film (the barrier film 12) capable of preventing diffusion of the second metal (e.g., copper) to the first insulation film 10, it becomes possible to more reliably prevent the second metal (e.g., copper) from diffusing from the metal plating film (e.g., the copper plating film 15) to the first insulation film 10.

### Third Exemplary Embodiment

Next, a third exemplary embodiment of the present invention will be described in detail using the drawings. In the description below, configurations that are the same as those of the first exemplary embodiment or the second exemplary embodiment will be given the same reference numerals and detailed description of those configurations will be omitted. Further, configurations not specifically mentioned are the same as those of the first exemplary embodiment or the second exemplary embodiment.

### Configuration

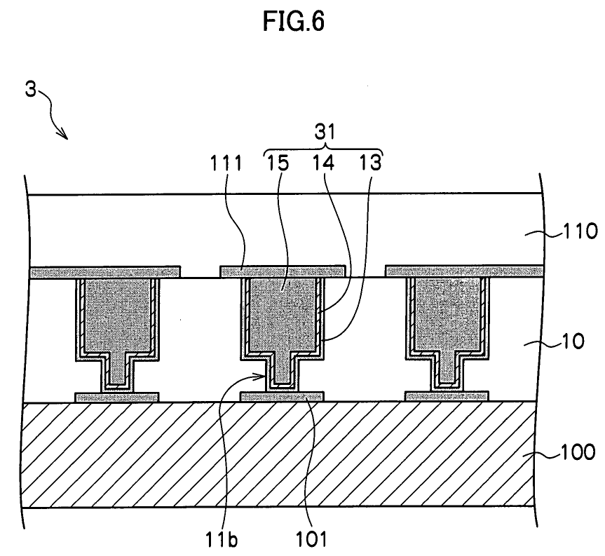

FIG. 6 is a cross-sectional diagram showing the configuration of a semiconductor device 3 according to the present exemplary embodiment. The cross-sectional diagram shown in FIG. 6 is a diagram when the semiconductor device 3 is cut along a plane that is perpendicular to the surface of the semiconductor substrate 100.

As shown in FIG. 6, the semiconductor device 3 includes a configuration where, in a configuration that is the same as that of the semiconductor device 1 according to the first exemplary embodiment, the second wires 11 are replaced by second wires 31.

The second wires 31 include a configuration where, in a configuration that is the same as that of the second wires 11 according to the first exemplary embodiment, the barrier film 12 is omitted. However, in the first exemplary embodiment, a film functioning as a diffusion barrier film that prevents diffusion of copper atoms, such as a ruthenium (Ru) film or a tungsten (W) film, was used as the glue film 14. For this reason, the glue film 14 itself is capable of functioning as the barrier film 12. Thus, in the present exemplary embodiment, the barrier film 12 of the second wires 11 is omitted.

The remaining configurations are the same as those of the semiconductor device 1 according to the first exemplary embodiment, so detailed description thereof will be omitted here.

### Fabrication Method

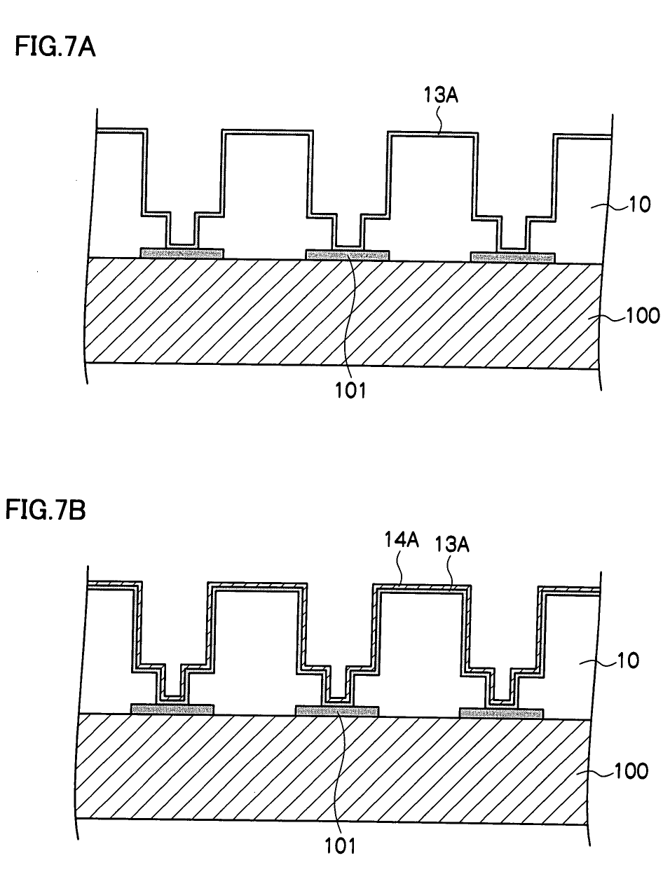

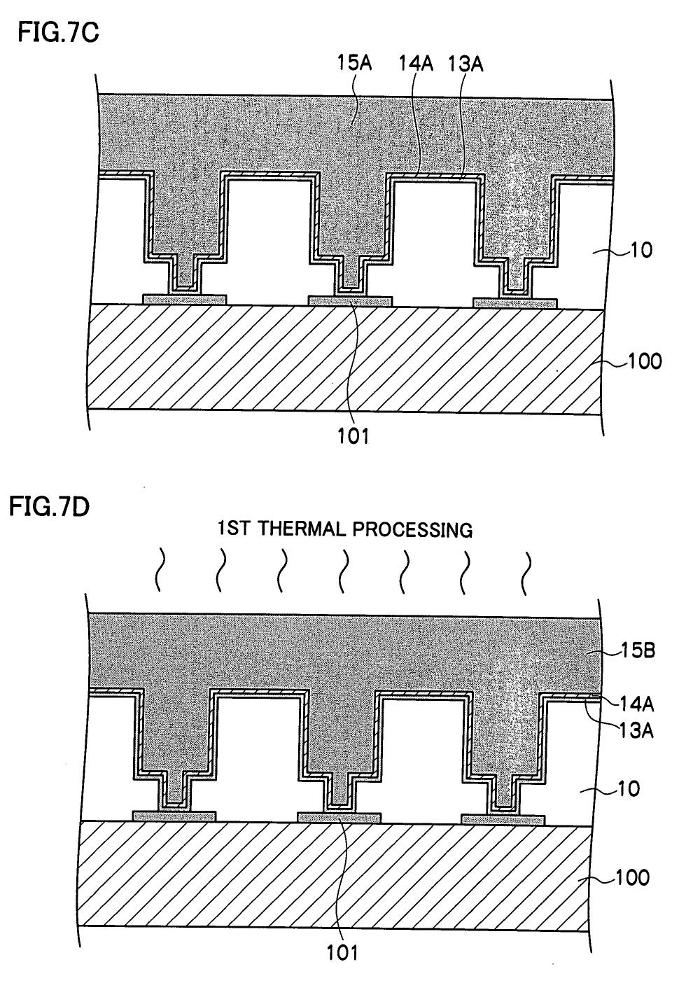

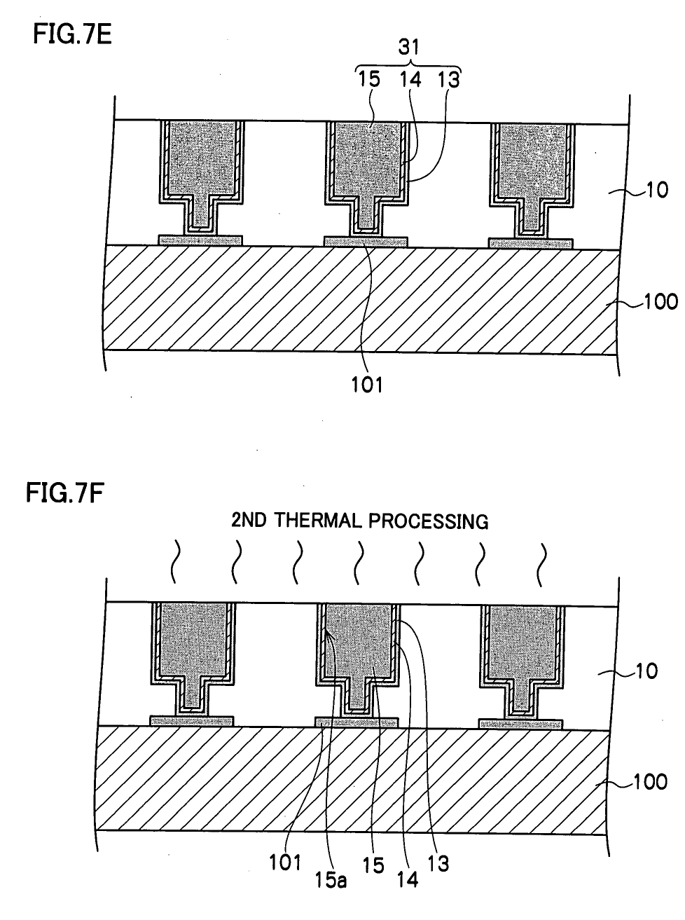

Next, a method of fabricating the semiconductor device 3 including the above configuration will be described in detail together with the drawings. FIG. 7A to FIG. 7F are process diagrams showing the method of fabricating the semiconductor device 3 according to the present exemplary embodiment. The steps shown in FIG. 2A and FIG. 2B of the first exemplary embodiment are also the same in the present exemplary embodiment, so they will be quoted and described here.

In the present fabrication method, first, the semiconductor substrate 100 on which elements such as transistors, capacitors and resistors have been formed is prepared. Next, a conductor film comprising copper and aluminium is formed on the semiconductor substrate 100, and this is worked using publicly known photolithographic techniques and etching techniques, whereby a conductor pattern including the first wires 101 is formed on the semiconductor substrate 100. Next, an insulator such as silicon dioxide is deposited on the semiconductor substrate 100 using the CVD method, for example, whereby the first insulation film 10 is formed. Thus, the layer structure shown in FIG. 2A is obtained.

Next, the first insulation film 10 formed on the semiconductor substrate 100 is worked using publicly known photolithographic techniques and etching techniques, whereby the grooves 11a whose width is 0.2 μm and whose depth is 0.3 μm, for example, are formed in the first insulation film 10. Next, the first insulation film 10 in the bottom portions of the grooves 11a is similarly worked using publicly known photolithographic techniques and etching techniques, whereby the through holes 11b whose open shape diameters are 0.2 μm and whose depth is 0.3 μm, for example, are formed as shown in FIG. 2B.

The steps up to here are the same as those of the fabrication method in the first exemplary embodiment. In the present exemplary embodiment, next, titanium (Ti) is deposited using the plasma CVD method, for example, whereby, as shown in FIG. 7A, a doping material film 13A comprising a titanium film whose film thickness is about 10 nm, for example, is formed on the first insulation film 10 and inside the grooves 11a and the through holes 11b. In the film forming conditions at this time, TiCl₄ can be used as the raw material gas, H₂ can be used as the reducing gas, and the substrate temperature can be about 400 to 450° C. However, as mentioned above, in addition to titanium (Ti), any one or more of the following can also be applied as the doping material: lithium (Li), beryllium (Be), boron (B), magnesium (Mg), aluminium (Al), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb).

Next, ruthenium (Ru) is deposited using the ALD method, for example, whereby a glue film 14A comprising a ruthenium film whose film thickness is about 10 nm, for example, is formed on the doping material film 13A as shown in FIG. 7B. In the film forming conditions at this time, RuCp2 (Cp=cyclopentadienyl) can be used as the metal precursor, O₂ can be used as the reaction gas, and the substrate temperature can be about 300 to 400° C. However, in addition to ruthenium (Ru), tungsten (W) or the like, for example, can also be applied as the material of the glue film 14A when forming a copper plating film 15A (see FIG. 7C) by the electrolytic plating method.

In the above description, an example is given where the CVD method (the ALD method) is used to form the doping material film 13A and the glue film 14A, but the present invention is not limited to this; similar to the first exemplary embodiment, various film forming methods such as the sputtering method can also be applied.

As described above, when the laminate film comprising the doping material 13A and the glue film 14A is formed, next, the electrolytic plating method is used, whereby, as shown in FIG. 7C, a copper plating film 15A that completely fills the grooves 11a and the through holes 11b formed in the first insulation film 10 is formed on the glue film 14A. Because it is possible to use publicly known conditions in the electrolytic plating method at this time, detailed description will be omitted here.

Next, as shown in FIG. 7D, first thermal processing is administered to the copper plating film 15A formed by the electrolytic plating method. Thus, the copper plating film 15A changes in nature to a copper plating film 15B. The first thermal processing is the same as that of the first exemplary embodiment, so detailed description will be omitted here.

Next, the copper plating film 15B, the glue film 14A and the doping material film 13A are sequentially polished using the chemical and mechanical polishing (CMP) method, for example, until the upper surface of the first insulation film 10 is exposed. Thus, as shown in FIG. 7E, each of the conductor layers (13A, 14A, 15B) on the first insulation film 10 is removed while the second wires 31 comprising the doping material film 13, the glue film 14 and the copper plating film 15 remain inside the grooves 11a and the through holes 11b. Similar to the first exemplary embodiment, a polishing step comprising two steps can be used for the polishing at this time.

Next, second thermal processing is administered to the second wires 31 remaining inside the grooves 11a and the through holes 11b. Thus, as shown in FIG. 7E, the doping material (in the present example, titanium (Ti) atoms) in the doping material film 13 diffuses to the copper plating film 15 via the glue film 14, and a copper plating film including the doping material (the doping material-including conductive layer 15a) is formed at the boundary surface between the copper plating film 15 and the glue film 14. The second thermal processing is the same as that of the first exemplary embodiment, so detailed description will be omitted here.

When the doping material-including conductive layer 15a is formed as described above, next, a conductor film comprising copper and aluminium is formed on the first insulation film 10 on which the second wires 31 have been formed, and this is worked using publicly known photolithographic techniques and etching techniques, whereby a conductor pattern including the third wires 111 is formed on the first insulation film 10. Next, an insulator such as silicon dioxide is deposited on the first insulation film 10 by the CVD method, for example, whereby the second insulation film 110 is formed. Thus, the semiconductor device 3 shown in FIG. 6 is fabricated.

As described above, the semiconductor device 3 according to the present exemplary embodiment is configured to include: the semiconductor substrate 100; the first insulation film 10 that is formed on the semiconductor substrate 100 and includes the grooves 11a (including the through holes 11b); the glue film 14 formed inside the grooves 11a; and a metal plating film (the copper plating film 15) that is formed on a side surface of the glue film 14, includes a region (the doping material-including conductive layer 15a) having a first metal (e.g., titanium) in a surface that contacts the glue film 14, and is formed by a second metal (e.g., copper).

As mentioned above, the film formed by any one or more of ruthenium (Ru) and tungsten (W), for example, is a film capable of functioning as a seed layer (the glue film 14) when depositing the second metal such as copper by the electrolytic plating method. Further, the glue film 14 formed by any one or more of these can be formed using a thin film forming method such as the ALD method, for example. For this reason, using a film formed by any one or more of ruthenium (Ru) and tungsten (W) as the glue film 14 during electrolytic plating becomes advantageous when forming the second wires 31 comprising a metal plating film (e.g., the copper plating film 15) inside the grooves 11a and the through holes 11b whose aspect ratio is large. Further, by disposing a region (the doping material-including layer 15a) where the first metal (e.g., titanium) that is different from the second metal (e.g., copper) is included in the surface of the metal plating film (e.g., the copper plating film 15) that contacts the glue film 14, concavo-convexities are formed in, or a reaction layer is formed on, the contact surface between the metal plating film (e.g., the copper plating film 15) and the glue film 14. For this reason, it becomes possible to strengthen one or both of the physical bonding force resulting from the anchor effect by forming concavo-convexities and the chemical bonding force by forming a reaction layer. That is, it becomes possible to realize the semiconductor device 3 that has excellent adhesiveness and is capable of ensuring high reliability. Moreover, when using a material capable of preventing diffusion of the second metal (e.g., copper) such as ruthenium as the material of the glue film 14, the diffusion barrier film (the barrier film 12) that has conventionally been necessary becomes unnecessary, so simplification of the configuration and the fabrication method can be realized, and it becomes possible to form wires comprising a metal plating film (e.g., the copper plating film 15) in the grooves 11a and the through holes 11b whose aspect ratio is larger.

### Fourth Exemplary Embodiment

Next, a fourth exemplary embodiment of the present invention will be described in detail using the drawings. In the description below, configurations that are the same as those of any of the first exemplary embodiment to the third exemplary embodiment will be given the same reference numerals and detailed description of those configurations will be omitted. Further, configurations not specifically mentioned are the same as those of any of the first exemplary embodiment to the third exemplary embodiment.

### Configuration

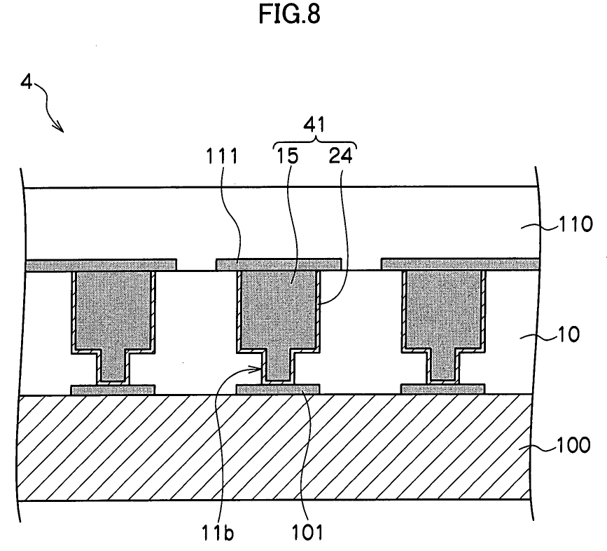

FIG. 8 is a cross-sectional diagram showing the configuration of a semiconductor device 4 according to the present exemplary embodiment. The cross-sectional diagram shown in FIG. 8 is a diagram when the semiconductor device 4 is cut along a plane that is perpendicular to the surface of the semiconductor substrate 100.

As shown in FIG. 8, the semiconductor device 4 includes a configuration where, in a configuration that is the same as that of the semiconductor device 1 according to the first exemplary embodiment, the second wires 11 are replaced by second wires 41.

The second wires 41 include a configuration where, in a configuration that is the same as that of the second wires 21 according to the second exemplary embodiment, the barrier film 12 is omitted. However, in the second exemplary embodiment, a material functioning as a diffusion barrier film that prevents diffusion of copper atoms, such as a ruthenium (Ru) film or a tungsten (W) film, was used as the main configural material of the doping material-including glue film 24. For this reason, the doping material-including glue film 24 itself is capable of functioning as the barrier film 12. Thus, in the present exemplary embodiment, the barrier film 12 of the second wires 21 is omitted.

The remaining configurations are the same as those of the semiconductor device 1 according to the first exemplary embodiment, so detailed description thereof will be omitted here.

### Fabrication Method

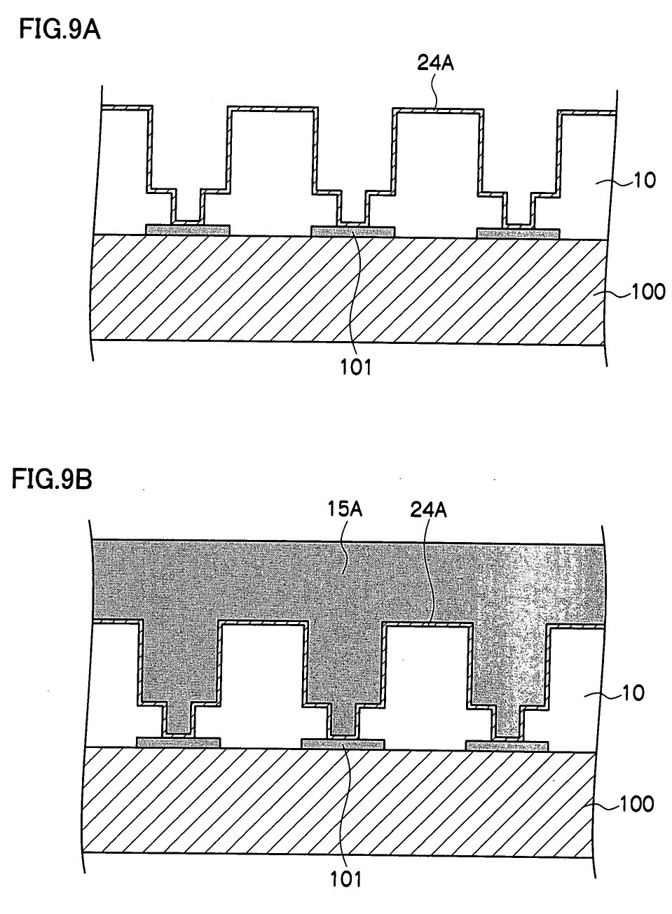

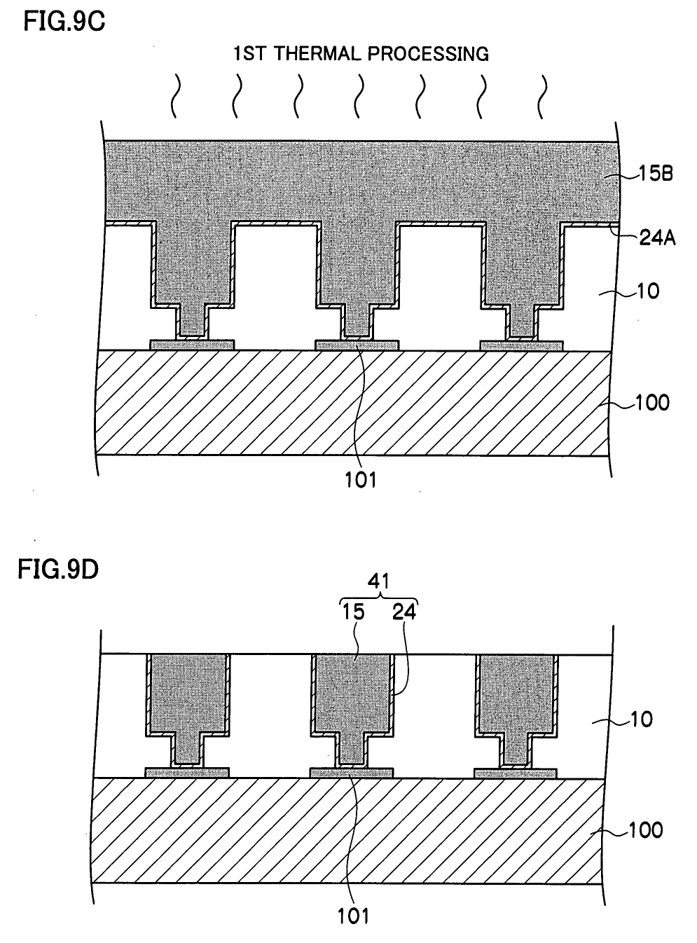

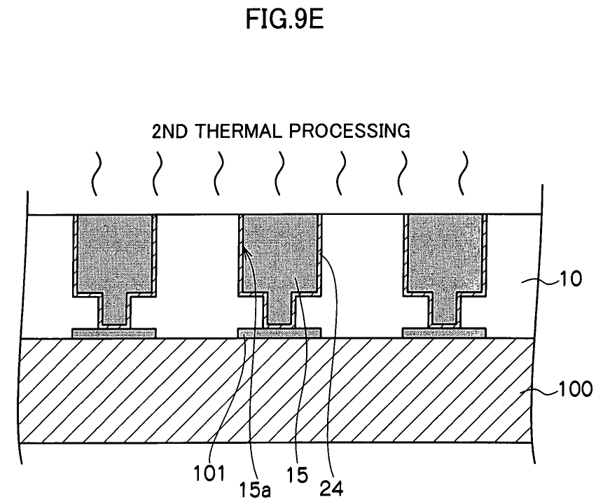

Next, a method of fabricating the semiconductor device 4 including the above configuration will be described in detail together with the drawings. FIG. 9A to FIG. 9E are process diagrams showing the method of fabricating the semiconductor device 4 according to the present exemplary embodiment. The steps shown in FIG. 2A and FIG. 2B of the first exemplary embodiment are also the same in the present exemplary embodiment, so they will be quoted and described here.

In the present fabrication method, first, the semiconductor substrate 100 on which elements such as transistors, capacitors and resistors have been formed is prepared. Next, a conductor film comprising copper and aluminium is formed on the semiconductor substrate 100, and this is worked using publicly known photolithographic techniques and etching techniques, whereby a conductor pattern including the first wires 101 is formed on the semiconductor substrate 100. Next, an insulator such as silicon dioxide is deposited on the semiconductor substrate 100 using the CVD method, for example, whereby the first insulation film 10 is formed. Thus, the layer structure shown in FIG. 2A is obtained.

Next, the first insulation film 10 formed on the semiconductor substrate 100 is worked using publicly known photolithographic techniques and etching techniques, whereby the grooves 11a whose width is 0.2 μm and whose depth is 0.3 μm, for example, are formed in the first insulation film 10. Next, the first insulation film 10 in the bottom portions of the grooves 11a is similarly worked using publicly known photolithographic techniques and etching techniques, whereby the through holes 11b whose open shape diameters are 0.2 μm and whose depth is 0.3 μm, for example, are formed as shown in FIG. 2B.

The steps up to here are the same as those of the fabrication method in the first exemplary embodiment. In the present exemplary embodiment, next, ruthenium (Ru) and titanium (Ti) are deposited using the sputtering method, for example, whereby a ruthenium film including titanium (a doping material-including glue film 24A) is formed on the first insulation film 10 and inside the grooves 11a and the through holes 11b. In the film forming conditions at this time, the pressure of the sputtering atmosphere can be about 2 mTorr, the DV power can be about 10 kW, and the film forming temperature can be about 30° C. As the material functioning as the glue film in the doping material-including glue film 24A, tungsten (W) or the like, for example, can also be applied in addition to ruthenium (Ru). Further, in addition to titanium (Ti), any one or more of the following can also be applied as the doping material included therein: lithium (Li), beryllium (Be), boron (B), magnesium (Mg), aluminium (Al), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb). Because of this step, as shown in FIG. 9A, a doping material-including glue film 24A whose film thickness is about 10 nm is formed on the first insulation film 10 and inside the grooves 11a.

In the above description, an example is given where the sputtering method is used to form the doping material-including glue film 24A, but the present invention is not limited to this; various film forming methods such as the CVD (ALD) method can also be applied.

As described above, when the doping material-including glue film 24A is formed, next, the electrolytic plating method is used, whereby, as shown in FIG. 9B, a copper plating film 15A that completely fills the grooves 11a and the through holes 11b formed in the first insulation film 10 is formed on the doping material-including glue film 24A. Because it is possible to use publicly known conditions in the electrolytic plating method at this time, detailed description will be omitted here.

Next, as shown in FIG. 9C, first thermal processing is administered to the copper plating film 15A formed by the electrolytic plating method. Thus, the copper plating film 15A changes in nature to a copper plating film 15B. The first thermal processing is the same as that of the first exemplary embodiment, so detailed description will be omitted here.

Next, the copper plating film 15B and the doping material-including glue film 24A are sequentially polished using the CMP method, for example, until the upper surface of the first insulation film 10 is exposed. Thus, as shown in FIG. 9D, each of the conductor layers (24A, 15B) on the first insulation film 10 is removed while the second wires 41 comprising the doping material-including glue film 24 and the copper plating film 15 remain inside the grooves 11a and the through holes 11b. Similar to the first exemplary embodiment, a polishing step comprising two steps can be used for the polishing at this time.

Next, second thermal processing is administered to the second wires 41 remaining inside the grooves 11a and the through holes 11b. Thus, as shown in FIG. 9E, the doping material (in the present example, titanium (Ti) atoms) in the doping material-including glue film 24 diffuses to the copper plating film 15 via the glue film 14a, and a copper plating film including the doping material (the doping material-including conductive layer 15a) is formed at the boundary surface between the copper plating film 15 and the glue film 14a. The second thermal processing is the same as that of the first exemplary embodiment, so detailed description will be omitted here. Further, in the case of a configuration where the glue film 14a is not formed, the doping material (in the present example, titanium (Ti)) thermally diffuses directly from the doping material-including glue film 24 to the copper plating film 15, and a copper plating film including the doping material (the doping material-including conductive layer 15a) is formed at the boundary surface between the copper plating film 15 and the doping material-including glue film 24.

When the doping material-including conductive layer 15a is formed as described above, next, a conductor film comprising copper and aluminium is formed on the first insulation film 10 on which the second wires 41 have been formed, and this is worked using publicly known photolithographic techniques and etching techniques, whereby a conductor pattern including the third wires 111 is formed on the first insulation film 10. Next, an insulator such as silicon dioxide is deposited on the first insulation film 10 by the CVD method, for example, whereby the second insulation film 110 is formed. Thus, the semiconductor device 4 shown in FIG. 8 is fabricated.

As described above, the semiconductor device 4 according to the present exemplary embodiment is configured to include: the semiconductor substrate 100; the first insulation film 10 that is formed on the semiconductor substrate 100 and includes the grooves 11a (including the through holes 11b); the doping material-including glue film 24 formed inside the grooves 11a; and a metal plating film (the copper plating film 15) that is formed on a side surface of the doping material-including glue film 24, includes a region (the doping material-including conductive layer 15a) having a first metal (e.g., titanium) in a surface that contacts the doping material-including glue film 24, and is formed by a second metal (e.g., copper).

As mentioned above, the film formed by any one or more of ruthenium (Ru) and tungsten (W), for example, is a film capable of functioning as a seed layer (the glue film 14) when depositing the second metal such as copper by the electrolytic plating method. Further, the glue film 14 formed by any one or more of these can be formed using a thin film forming method such as the ALD method, for example. For this reason, using a film formed by any one or more of ruthenium (Ru) and tungsten (W) as the glue film 14 during electrolytic plating becomes advantageous when forming the second wires 41 comprising a metal plating film (e.g., the copper plating film 15) inside the grooves 11a and the through holes 11b whose aspect ratio is large. Further, by disposing a region (the doping material-including layer 15a) where the first metal (e.g., titanium) that is different from the second metal (e.g., copper) is included in the surface of the metal plating film (e.g., the copper plating film 15) that contacts the glue film 14, concavo-convexities are formed in the contact surface between the metal plating film (e.g., the copper plating film 15) and the glue film 14, so it becomes possible to strengthen one or both of chemical bonding force and physical bonding force resulting from the anchor effect. That is, it becomes possible to realize the semiconductor device 4 that has excellent adhesiveness and is capable of ensuring high reliability. Moreover, when using a material capable of preventing diffusion of the second metal (e.g., copper) such as ruthenium as the material of the glue film (the doping material-including glue film 24), the diffusion barrier film (the barrier film 12) that has conventionally been necessary becomes unnecessary, so simplification of the configuration and the fabrication method can be realized, and it becomes possible to form the second wires 41 comprising a metal plating film (e.g., the copper plating film 15) in the grooves 11a and the through holes 11b whose aspect ratio is larger. Moreover, by configuring the semiconductor device such that the first metal (e.g., titanium) to be diffused to the metal plating film (e.g., the copper plating film 15) is included in the glue film (the doping material-including glue film 24), it becomes unnecessary to separately dispose a film including the first metal (e.g., titanium) that is used as the doping material, so it becomes possible to further simplify the configuration and fabrication method.

The first exemplary embodiment to the fourth exemplary embodiment are only examples for implementing the present invention, and the present invention is not limited to these. Variously modifying these exemplary embodiments is within the scope of the present invention, and it will be apparent from the above description that various other embodiments are possible within the scope of the present invention.

What is claimed is:

1. A semiconductor device comprising:
a semiconductor substrate;
an insulation film that is formed on the semiconductor substrate and includes grooves;
a glue film formed inside the grooves; and
a metal plating film that is formed on a side surface of the glue film, includes a region having a first metal in a surface that contacts the glue film, and is formed by a second metal.

2. The semiconductor device of claim 1, further comprising a metal film that is formed between the insulation film and the glue film inside the grooves and includes the first metal.

3. The semiconductor device of claim 1, wherein the glue film includes the first metal.

4. The semiconductor device of claim 1, wherein the glue film is capable of preventing diffusion of the second metal via the glue film.

5. The semiconductor device of claim 1, wherein the glue film is a film comprising any one or more of ruthenium (Ru) and tungsten (W).

6. The semiconductor device of claim 1, wherein the first metal is configured by any one or more of lithium (Li), beryllium (Be), boron (B), magnesium (Mg), aluminium (Al), titanium (Ti), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb).

7. The semiconductor device of claim 1, wherein the second metal is copper (Cu).

8. The semiconductor device of claim 1, further comprising a diffusion barrier film that is a film formed between side surfaces of the grooves and the glue film and prevents the second metal from diffusing via the film.

9. A semiconductor device fabrication method comprising:
forming an insulation film on a semiconductor substrate;
forming grooves in the insulation film;
forming a metal film including a first metal inside the grooves and on the insulation film;
forming a glue film on the metal film;
forming, on the glue film by an electrolytic plating method, a metal plating film that completely fills the grooves and comprises a second metal;
evenly polishing the metal plating film, the glue film and the metal film from above to expose an upper surface of the insulation film and form wires comprising the metal plating film, the glue film and the metal film inside the grooves; and
thermally processing the wires to cause the first metal to diffuse from the metal film to the metal plating film to form a region having the first metal in a surface of the metal plating film that contacts the glue film.

10. The semiconductor device fabrication method of claim 9, wherein the glue film is capable of preventing diffusion of the second metal via the glue film.

11. The semiconductor device fabrication method of claim 9, wherein the glue film is a film comprising any one or more of ruthenium (Ru) and tungsten (W).

12. The semiconductor device fabrication method of claim 9, wherein the first metal is configured by any one or more of lithium (Li), beryllium (Be), boron (B), magnesium (Mg), aluminium (Al), titanium (Ti), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb).

13. The semiconductor device fabrication method of claim 9, wherein the second metal is copper (Cu).

14. The semiconductor device fabrication method of claim 9, further comprising growing crystal grains of the second metal by thermally processing the metal plating film before forming the region having the first metal in the surface of the metal plating film that contacts the glue film.

15. The semiconductor device fabrication method of claim 9, further comprising forming, between side surfaces of the grooves and the glue film, a diffusion barrier film that prevents the second metal from diffusing via the film.

16. A semiconductor device fabrication method comprising:
forming an insulation film on a semiconductor substrate;
forming grooves in the insulation film;
forming a glue film having a first metal inside the grooves and on the insulation film;
forming, on the glue film by an electrolytic plating method, a metal plating film that completely fills the grooves and comprises a second metal;
evenly polishing the metal plating film and the glue film from above to expose an upper surface of the insulation film and form wires comprising the metal plating film and the glue film inside the grooves; and
thermally processing the wires to cause the first metal to diffuse from the glue film to the metal plating film to form a region having the first metal in a surface of the metal plating film that contacts the glue film.

17. The semiconductor device fabrication method of claim 16, wherein the glue film is capable of preventing diffusion of the second metal via the glue film.

18. The semiconductor device fabrication method of claim 16, wherein the glue film is a film comprising any one or more of ruthenium (Ru) and tungsten (W).

19. The semiconductor device fabrication method of claim 16, wherein the first metal is configured by any one or more of lithium (Li), beryllium (Be), boron (B), magnesium (Mg), aluminium (Al), titanium (Ti), silicon (Si), scandium (Sc), vanadium (V), chromium (Cr), manganese (Mn), nickel (Ni), zinc (Zn), gallium (Ga), germanium (Ge), selenium (Se), bromine (Br), rubidium (Rb), strontium (Sr), yttrium (Y), zirconium (Zr), niobium (Nb), molybdenum (Mo), silver (Ag), indium (In), tin (Sn), antimony (Sb), tellurium (Te), barium (Ba), hafnium (Hf), rhenium (Re), gold (Au), iridium (Ir), platinum (Pt), and lead (Pb).

20. The semiconductor device fabrication method of claim 16, wherein the second metal is copper (Cu).

21. The semiconductor device fabrication method of claim 16, further comprising growing crystal grains of the second metal by thermally processing the metal plating film before forming the region having the first metal in the surface of the metal plating film that contacts the glue film.

22. The semiconductor device fabrication method of claim 16, further comprising forming, between side surfaces of the grooves and the glue film, a diffusion barrier film that prevents the second metal from diffusing via the film.
